(19) United States
(12) Patent Application Publication
(10) Pub. No.: US 2021/0198099 A1
(43) Pub. Date: Jul. 1, 2021

(54) HERMETIC PACKAGE COMPRISING A GETTER, PART COMPRISING SUCH A HERMETIC PACKAGE, AND ASSOCIATED MANUFACTURING PROCESS

(71) Applicant: LYNRED, Palaiseau (FR)

(72) Inventors: Sylvain Lemettre, Massy (FR); David Bunel, Moirans (FR)

(21) Appl. No.: 17/057,842

(22) PCT Filed: Jun. 19, 2019
(86) PCT No.: PCT/FR2019/051493

§ 371 Date: Nov. 23, 2020

(30) Foreign Application Priority Data
Jul. 6, 2018 (FR) 1856223

(51) Int. Cl. B81B 7/00

(52) U.S. Cl. CPC B81B 7/0038; B81B 2207/09

(57) ABSTRACT

The invention concerns a hermetically sealed package forming a low pressure or vacuum enclosure, and receiving at least one component of imaging bolometer type. The hermetically sealed package includes a monolithic layer of a getter material capable of capturing gases present in the enclosure, the layer of getter material having a thickness in the range from 20 nanometers to 200 nanometers.

### FIELD OF TECHNOLOGY

The invention concerns a hermetically sealed package configured to form an enclosure having a determined pressure inside of it and intended to receive a component requiring a low pressure or vacuum for its operation. The invention also concerns a component of imaging bolometer type encapsulated in such a hermetically sealed package. It eventually concerns a method of forming such a hermetically sealed package.

In the sense of the invention, a component of imaging bolometer type corresponds to a component comprising a membrane suspended on a substrate. Preferably, the substrate is covered with a reflector and the walls and/or the upper portion of the enclosure support the getter material.

### BACKGROUND

To form a package under vacuum or under a low pressure, it is known to use a pumping of the air in an enclosure, followed by the sealing of the walls forming the package, particularly by metal welding. However, performing a metal welding generates a heating of the enclosure, causing the desorption of the gas molecules trapped on its walls. When the package is sealed, the gases in the package can no longer be discharged by the pumping system, so that a specific absorption device should be positioned within the package to remove the gases resulting from the desorption of the walls and present within said package. Such an absorption device is called “getter”.

A getter appears in the form of a metal layer deposited on one of the package walls. The getter is initially passivated. The passivation is performed by its native oxide if it has been exposed to ambient air or by a layer of a noble metal covering the getter. It is thus necessary to activate the getter to cause a dissolving of the native oxide or of the noble metal layer across the volume of the metal layer, then making the getter reactive.

The activation is conventionally achieved by heating the getter. Due to the heating, the atoms of the passivation layer have diffused into the metal layer of the getter and the surface of the metal layer is capable of capturing the gases present in the package, thus lowering the pressure inside of it. The getter is then said to be “activated”.

The level of vacuum reached in an enclosure is controlled by the quantity of gas molecules absorbed by the getter. This quantity depends on the activation conditions and on the properties of the getter, that is, on its chemical nature, on its microstructure, and on the extent of its surface in contact with the gases of the enclosure.

Concerning the getter activation conditions, a diffusion of atoms from the passivation layer into the volume of the getter is desired. To ease the diffusion, the getter should have a high density of grain boundaries, since the diffusion is faster through grain boundaries than within grains. Further, during the activation, the quantity of desorbed gas is proportional to the anneal temperature. Thus, with a high density of grain boundaries, it is possible to limit the activation temperature of the getter and thus to limit the desorption of gas molecules into the enclosure to obtain a very low pressure.

However, the size of the grains at the surface of a getter increases when the thickness of the getter increases. At the same time, it is also known that an insufficiently thick getter cannot regenerate the metallic character of its surface, since the impurity atoms forming the passivation layer cannot fully diffuse into the getter.

Indeed, as described in document U.S. Pat. No. 7,998,319, with low thicknesses, the gas sorption properties are excessively low due to the fact that thin deposits tend to follow the morphology of the surface on which they grow, which results in too smooth and compact a surface to have good sorption characteristics.

Thus, documents US 2016/0040282, U.S. Pat. Nos. 9,309,110, and 7,998,319 indicate that getter films having a thickness smaller than 200 nanometers are considered as non-functional. The technical issue targeted by the invention is to provide a hermetically sealed package with a layer of getter material having a microstructure which enables to more efficiently comply with the constraints of the activation conditions and of absorption needs.

### SUMMARY OF THE DISCLOSURE

The disclosure originates from a discovery according to which the thickness of a getter material only contributes to regenerating the metallic character of its surface across a very small thickness, typically smaller than 20 nanometers. Conversely to the common belief in the state of the art, the disclosed embodiments thus provide using a layer of a getter material having a thickness in the range from 20 to 200 nanometers.

The calculation of this minimum 20-nanometer thickness value is a theoretical calculation performed for titanium by mister L. TENCHINE in his 2011 thesis of the Grenoble University (France) entitled “Effet getter de multicouches métalliques pour des applications MEMS”, page 138. It is the thickness necessary for the oxygen concentration of the film to be smaller than its solubility limit, after the absorption of the oxygen atoms originating from its passivation layer. Since titanium is the material having the highest solubility limit for oxygen, the minimum thicknesses which would be calculated for getter films formed of other materials would be greater than that of 20 nanometers of titanium.

For this purpose, according to a first aspect, the disclosure concerns a hermetically sealed package configured to form an enclosure under a predetermined pressure receiving a component of imaging bolometer type, said hermetically sealed package comprising a monolithic layer of a getter material capable of capturing gases present in said enclosure.

The presently disclosed embodiments are characterized in that said layer of getter material has a thickness in the range from 20 nanometers to 200 nanometers.

By discovering that it is possible to decrease the thickness of a monolithic layer of getter material below 200 nanometers, it is now possible to form a getter with a high grain boundary density, enabling to ease the getter activation, that is, by limiting the activation temperature or time.

In the sense of the disclosed embodiments, a “monolithic” layer of a getter material corresponds to a getter material formed of a single layer achieving the molecule desorption to maintain a desired pressure in a package.

Further, in the context of a deposition of the getter material by evaporation, the pressure in the enclosure increases during the deposition of the getter material, due to the progressive heating of the walls defining said enclosure, which goes along with a desorption of the molecules trapped in said walls.

During the deposition phase, certain contaminants present in the enclosure are incorporated (including argon) into the layer of getter material, which impurities adversely affect the properties of the getter. Further, the argon atoms will be desorbed by the getter into the package enclosure during the getter activation phase.

Thus, against all expectations, the decrease of the thickness of the getter material enables, by decreasing the activation temperature, on the one hand to obtain a purer getter, more efficient to absorb the gases present in the enclosure and, on the other hand, to obtain a greater level of vacuum in the package enclosure, by limiting the desorption of molecules unabsorbed by the getter, such as argon.

Other more obvious advantages also result from the use of a getter thinner than getter of the state of the art. Indeed, a thinner deposit takes shorter to achieve and consumes less raw material.

Further, the mechanical resistance between the getter and its support is inversely proportional to the getter thickness. As a result, the use of a thin getter limits the risk of separation of the getter from its support. Conventionally, the getter is arranged on a wall of the enclosure but the use of a thin getter enables to deposit the getter on an electronic component, such as a CMOS circuit, having its surface more sensitive than the wall to mechanical stress.

These advantages are increased when the getter thickness decreases, typically when the layer of getter material is deposited with a thickness in the range from 20 to 100 nanometers.

Further, it is preferable to use a non-porous getter material to form the low-thickness getter, to guarantee the absorption of the molecules of the passivation layer during the getter activation.

If the getter material is porous, the proportion of oxide that it contains is increased with respect to a non-porous film, and thus the minimum thickness necessary for its activation is greater.

Preferably, the layer of getter material has a porosity smaller than 5%. Such a porosity value is determined, in the sense of the disclosed embodiments, by using the BET method, named after its inventors Brunauer, Emmet, and Teller, such as described in S. Brunauer, P. H. Emmet, E. Teller's publication “Adsorption of gases in multimolecular layers”, Journal of the American Chemical Society, vol 60(2), pages 309-319 (1938). This method comprises measuring the porosity of a volume by adsorption of a gas and by quantification of the quantity of gas absorbed per volume unit. In other words, this method enables to measure the quantity of gas molecules adsorbed on the wall of the material, this quantity being proportional to the surface area of the wall. This method is standardized and all its parameters are described in standard ISO 44941.

To increase the surface area of getter contact with the gases present in the enclosure, the layer of getter material may have a base topped with a structuring pattern, the thickness of the base being greater than 20 nanometers.

In this embodiment, the thickness of the base guarantees the absorption of the molecules of the passivation layer (native oxide) during the getter activation and the structuring pattern enables to increase the gas volume captured by the getter.

Typically, the layer of getter material may be configured to guarantee a pressure smaller than 10⁻³ mbar in the enclosure. This embodiment enables to reach a maximum sensitivity for imaging bolometers, and in particular for uncooled microbolometers in infrared imaging.

The layer of getter material may be made of zirconium, of titanium, of vanadium, of hafnium, of niobium, of tantalum, of cobalt, of yttrium, of barium, of iron, or of an alloy of these materials.

Such metals enable to obtain the desired absorption properties. Of course, the contemplated embodiments are not limited to the use of these materials and all transition metals, plus barium and aluminum, may be used as a getter

Further, said layer of getter material may be formed with rare earths or aluminum.

This embodiment enables the surface of the getter material to keep a reactive character after the chemisorption of the gas molecules, and thus to obtain a surface with a microstructure favorable to the absorption of gases in the enclosure.

According to a second aspect, the disclosure concerns a component of imaging bolometer type comprising a hermetically sealed package according to the first aspect of the disclosure.

According to a third aspect, the disclosure concerns a method of manufacturing a component of imaging bolometer type according to the second aspect of the disclosure, said method comprising a step of evaporation physical vapor deposition (PVD) of a layer of a getter material with a thickness in the range from 20 to 200 nanometers.

With the known thickness of getters of the state of the art, it is desired to increase the getter porosity to increase the gas absorption capacity in the enclosure.

Thus, getters are conventionally deposited according to the cathode sputtering technique, since the latter enables to obtain porous getters.

The method of physical vapor deposition by evaporation is even considered in as inappropriate in document U.S. Pat. No. 7,998,319, since it would not enable to obtain a getter with the porosity necessary for the proper operation of a getter.

Against all expectations, the third aspect of the disclosed embodiments provide using the method of physical vapor deposition by evaporation to form a compact getter of small thickness, enabling to obtain all the previously-described advantages.

According to an embodiment, the method comprises a structuring of the deposit of the layer of getter material on a substrate carried out by:

a first step of deposition of a resin layer on said substrate;

a second step of structuring of said resin layer by photolithography;

a third step of deposition of said layer of getter material by physical vapor deposition (PVD) by evaporation; and

a fourth step of dissolving of said resin layer.

This method is called “lift-off” in literature. For example, document U.S. Pat. No. 7,998,319 describes the structuring of the getter by photolithography followed by the deposition of a getter by cathode sputtering.

However, the structuring method induces significant mechanical stress on the resin layer during the deposition of the getter material, and there is a risk of separation of the getter film from the resin layer during the deposition of the getter material. Thus, this method is conventionally used with a deposition of the layer of getter material by cathode sputtering since cathode sputtering enables to obtain more porous getters than physical vapor deposition by evaporation, which limits the mechanical stress on the resin layer.

A method alternative to “lift-off” for the structuring of a getter material is the technique called “shadow masking” in literature. It comprises using a physical mask laid on the substrate and removed after the deposition of the getter. This technique is described in U.S. Pat. No. 8,912,620 for the deposition of a getter film. Such an alternative to “lift-off” for the structuring of the getter is less appropriate than the “lift-off” technique since it is more difficult to implement and much less accurate due to the diffraction of light after the passage through the ports of the etch mask.

Another known alternative method for the structuring of a getter deposit is to carry out:

a first step of deposition of said layer of getter material by physical vapor deposition (PVD) by evaporation;

a second step of deposition of a structured etch mask (by “lift off” or “shadow masking”) on said layer of getter material;

a third etch of selective etching of the getter material exposed through the openings of the etch mask; and

a fourth step of dissolving of said etch mask.

Such an alternative to “lift off” for the structuring of the getter is more difficult to implement than the “lift off” technique and the step of dissolving of the etch mask risks degrading the getter surface.

The small thickness of the getter of the disclosed embodiments enables to use the best known getter film structuring technique, that is, the simplest and the most accurate, which is “lift off”.

It may also be desired to obtain a layer of a getter material topped with a structuring pattern. For this purpose, it is possible to etch a monolithic getter layer deposited on a substrate.

Preferably, to obtain a structuring pattern on a layer of getter material, said method comprises a second step of deposition of a layer of a getter material on a previously-deposited layer of a getter material, said second deposition step being formed of:

a first step of deposition of a resin layer on said previously-deposited layer of getter material;

a second step of structuring of said resin layer by photolithography;

a third step of deposition of said new layer of a getter material by physical vapor deposition (PVD) by evaporation; and

a fourth step of dissolving of said resin layer.

This embodiment enables to use the “lift off” technique on a getter material previously deposited on a substrate to form a structuring pattern.

According to an embodiment, said method comprises a step of sealing said hermetically sealed package at a temperature in the range from 180° C. to 450° C. configured to ensure an activation of said layer of getter material. Advantageously, the step of sealing said hermetically sealed package is carried out at a temperature in the range from 250° C. to 320° C. This embodiment enables to carry out the activation of the layer of getter material directly during the step of sealing the hermetically sealed package by limiting the temperature applied to the package to decrease the molecule desorption. As a variant, said method comprises an activation step carried out by Joule effect by coupling the layer of getter material to a resistive circuit.

### BRIEF DESCRIPTION OF THE DRAWINGS

The way to implement the present embodiments, as well as the resulting advantages, will better appear from the description of the following non-limiting embodiment, given as an indication, based on the accompanying drawings, among which FIGS. 1 and 6 show:

FIG. 1: a simplified cross-section view of a component encapsulated in a package under a predetermined pressure according to an embodiment where the getter is arranged on an upper wall of the enclosure;

FIG. 2: a simplified cross-section view of a component encapsulated in a package under a predetermined pressure according to an embodiment where the getter is arranged on a substrate of the enclosure;

FIG. 3: a simplified cross-section view of the getter of FIG. 2 according to a first embodiment before the activation phase;

FIG. 4: a simplified cross-section view of the getter of FIG. 3 after the activation phase;

FIG. 5: a simplified cross-section view of the getter of FIG. 2 according to a second embodiment before the activation phase; and

FIG. 6: a simplified cross-section view of the getter of FIG. 5 after the activation phase.

### DETAILED DESCRIPTION

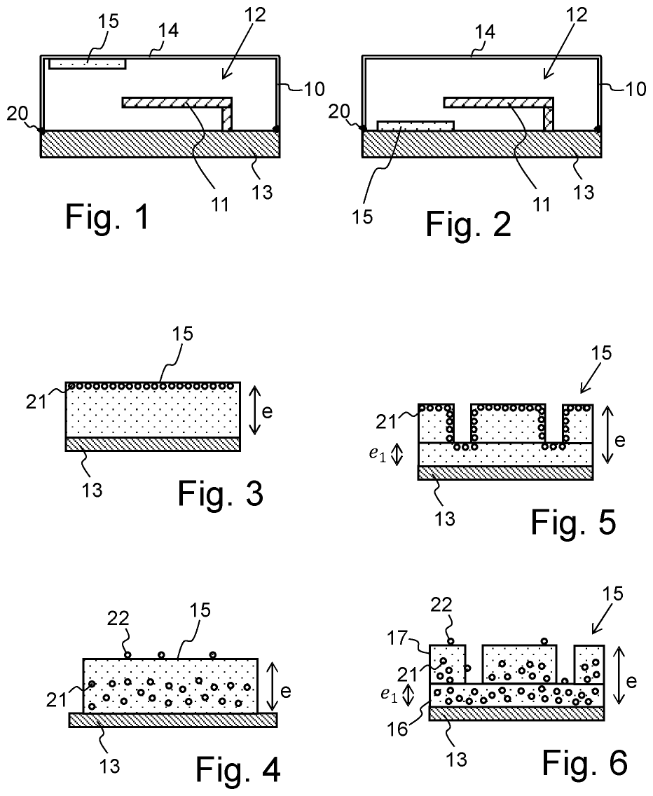

FIG. 1 illustrates a component 11 encapsulated in an enclosure 12 under a predetermined pressure, for example, under a pressure lower than 10⁻³ mbar. Component 11 corresponds to an imaging bolometer.

To guarantee the pressure in enclosure 12, a getter material 15 is arranged within the latter.

In the example of FIG. 1, enclosure 12 is formed by the sealing of walls 14 to a substrate 13 by means of a metal sealing joint 20, thus forming a hermetically sealed package 10 around component 11.

As a variant, package 10 may be formed by walls 14 arranged around one or a plurality of substrates 13 or by an assembly formed by walls 14 and one or a plurality of substrates 13.

Getter 15 has to be arranged in the volume defined by enclosure 12 to capture the gases present in enclosure 12 after the activation of said getter. In the example of FIG. 1, getter 15 is arranged on the inner surface of an upper wall 14 of package 10 opposite enclosure 12. In the example of FIG. 2, getter 15 is arranged on the upper surface of substrate 13 opposite enclosure 12.

Getter 15 has a thickness e in the range from 20 nanometers to 200 nanometers, and preferably from 20 nanometers to 100 nanometers. Preferably, getter 15 also has a porosity smaller than 5%. The getter may be made of zirconium (Zr), of titanium (Ti), of vanadium (V), of hafnium (Hf), of niobium (Nb), of tantalum (Ta), of cobalt (Co), of iron (Fe), of yttrium (Y), of barium (Ba), or of an alloy of these materials.

Further, aluminum (Al) and rare earths such as chromium (Cr), cerium (Ce), cesium (Cs), or lanthanum (La) may be added to these metals to improve the characteristics of getter 15, such as the grain size, the free oxide formation enthalpy, or the catalytic activity for the cracking of the gas molecules.

FIGS. 3 and 4 illustrate the process of activation of a solid, that is, non-structured getter 15. This type of getter 15 may be obtained by physical vapor deposition by evaporation.

Before the activation, as illustrated in FIG. 3, the upper surface of getter 15 in contact with air forms an oxide layer due to the presence of oxygen molecules in the air. By heating package 10, for example, to perform a sealing by metal welding 20 at a temperature in the range from 180° C. to 450° C., oxide atoms 21 migrate across thickness e of getter 15.

After the activation, as illustrated in FIG. 4, the atoms originating from oxide layer 21 are thus stored in thickness e of getter 15, and the gas molecules 22 present in the enclosure and resulting from their desorption out of the walls forming the enclosure may be captured by getter 15, having a surface, thus activated, which is highly reactive to gases capable of desorbing into the enclosure, and typically hydrogen, nitrogen, carbon dioxide, methane.

To increase the surface area of capture of the gas molecules present in enclosure 12, it is possible to structure the upper surface of getter 15 as illustrated in FIGS. 5 and 6. For this purpose, a lithography may be carried out on the upper surface to form a base 16 topped with a structuring pattern 17. Such a structuring may be formed by a deposition of resin and then again a getter deposition or a resin deposition and then etching.

In this embodiment, it is preferable for base 16 to have a thickness e₁ greater than 20 nanometers since oxide molecules 21 migrate, at least partly, into this base 16 during the activation, that is, between FIGS. 5 and 6. If the trenches extend all the way to the substrates, the diffusion of oxide molecules 21 may be performed laterally, that is, from the sides towards the inside.

In the description of FIGS. 1 to 6, getter 15 is described with an oxide layer 21 covering getter 15. As a variant, the contemplated embodiments may be carried out with a layer of noble metal protecting getter 15 before the activation. This layer of noble metal, for example, having a 20-nm thickness, would also be dissolved in the volume of getter 15 during the activation phase.

The activation phase is also described by heating during the thermal sealing of the package. As a variant, the activation may be carried out by Joule effect by coupling getter 15 to a resistive circuit without modifying the contemplated embodiments.

The disclosed embodiments thus provide using a thin getter 15, that is, with a thickness e in the range from 20 to 200 nm, and advantageously from 20 to 100 nanometers. As previously described, thin getter 15 enables to obtain a higher density of grain boundaries than getters of the state of the art, as well as a higher purity. Further, the thinness of getter 15 improves the resistance to mechanical stress, so that the lithography method may be used to structure getter 15.

The disclosed embodiments also enable to consume less material and to limit the manufacturing time of getter 15.

1. A hermetically sealed package forming a low pressure or vacuum enclosure, and receiving at least one component of imaging bolometer type, said hermetically sealed package comprising a monolithic layer of a getter material capable of capturing gases present in said enclosure, wherein the layer of getter material is deposited on the walls and/or the upper portion of said enclosure and has a thickness in the range from 20 nanometers to 200 nanometers, the layer of getter material being made of zirconium (Zr), of titanium (Ti), of vanadium (V), of hafnium (Hf), of niobium (Nb), of tantalum (Ta), of cobalt (Co), of yttrium (Y), of barium (Ba), of iron (Fe), or of an alloy of these materials.

2. The hermetically sealed package according to claim 1, wherein the layer of getter material has a thickness in the range from 20 nanometers to 100 nanometers.

3. The hermetically sealed package according to claim 1, wherein the layer of getter material has a porosity smaller than 5%.

4. The hermetically sealed package according to claim 1, wherein the layer of getter material has a base topped with a structuring pattern, the thickness of said base being greater than 20 nanometers.

5. (canceled)

6. The hermetically sealed package according to claim 1, wherein the layer of getter material is further formed with rare earths or aluminum (Al).

7. A component of imaging bolometer type, wherein said component comprises the hermetically sealed package according to claim 1.

8. A method of manufacturing the component of imaging bolometer type according to claim 7, wherein said method comprises a step of physical vapor deposition (PVD) by evaporation of a monolithic layer of a getter material with a thickness in the range from 20 to 200 nanometers.

9. The method of manufacturing a component according to claim 8, wherein said method comprises a structuring of the deposition of the layer of getter material on a substrate carried out by:
a first step of deposition of a resin layer on said substrate;
a second step of structuring of said resin layer by photolithography;
a third step of deposition of said layer of getter material by physical vapor deposition (PVD) by evaporation; and
a fourth step of dissolving of said resin layer.

10. The method of manufacturing a component according to claim 8, wherein said method comprises a second step of deposition of a layer of a getter material on a previously-deposited layer of a getter material, said second deposition step being carried out by:
a first step of deposition of a resin layer on said previously-deposited layer of getter material;
a second step of structuring of said resin layer by photolithography;
a third step of deposition of said new layer of getter material by physical vapor deposition (PVD) by evaporation; and
a fourth step of dissolving of said resin layer.

11. The method of manufacturing a component according to claim 8, wherein said method comprises a step of sealing said hermetically sealed package at a temperature in the range from 180° C. to 450° C., configured to ensure an activation of said layer of getter material.

12. The method of manufacturing a component according to claim 8, wherein said method comprises an activation step carried out by Joule effect by coupling the layer of getter material to a resistive circuit.
